(19) United States
(12) Patent Application Publication
(10) Pub. No.: US 2014/0145551 A1
(43) Pub. Date: May 29, 2014

(54) VIBRATOR, MANUFACTURING METHOD OF VIBRATOR, ELECTRONIC APPARATUS, AND MOVING OBJECT

(71) Applicant: Seiko Epson Corporation, Tokyo (JP)

(72) Inventors: Shogo Inaba, Shiojiri (JP); Masahiro Fujii, Shiojiri (JP)

(73) Assignee: Seiko Epson Corporation, Tokyo (JP)

(21) Appl. No.: 14/082,537

(22) Filed: Nov. 18, 2013

(30) Foreign Application Priority Data
Nov. 29, 2012 (JP) 2012-260744

(51) Int. Cl. B81B 3/00; B81C 1/00

(52) U.S. Cl. CPC B81B 3/0097; B81C 1/00166
USPC 310/300; 29/825

(57) ABSTRACT

A vibrator includes: a vibrating portion; a support portion extended from the vibrating portion; and a fixing portion disposed at the support portion, wherein the support portion includes a first beam portion extending in a first direction from the vibrating portion and a second beam portion extending in a second direction intersecting the first direction.

### BACKGROUND

1. Technical Field

The present invention relates to a vibrator, a manufacturing method of a vibrator, an electronic apparatus, and a moving object.

2. Related Art

In general, electromechanical system structures (for example, vibrators, filters, sensors, motors, and the like) including a mechanically movable structure that is formed using a semiconductor microfabrication technique and called a MEMS (micro electro mechanical system) device have been known. Among them, MEMS vibrators are easily manufactured incorporating a drive circuit of the vibrator or a circuit amplifying a change in vibration and thus advantageous for miniaturization and higher functionality, compared to vibrators or resonators using quartz crystal or a dielectric. Therefore, the MEMS vibrators are being expanded in application.

As representative examples of MEMS vibrators in the related art, a comb-type vibrator that vibrates in a direction parallel to a substrate surface on which the vibrator is disposed and a beam-type vibrator that vibrates in a thickness direction of a substrate have been known. The beam-type vibrator is a vibrator including a lower electrode (fixed electrode) formed on the substrate and a movable electrode (vibrating portion) disposed above the lower electrode with a gap. As the beam-type vibrator, a clamped-free beam vibrator, a clamped-clamped beam vibrator, a free-free beam vibrator, and the like have been known, depending on how to support the movable electrode.

In the free-free beam MEMS vibrator, the portion of node of vibration of the movable electrode that vibrates is supported by a support portion. Therefore, the free-free beam MEMS vibrator has reduced vibration leakage to the substrate and high vibration efficiency. U.S. Pat. No. 6,930,569 B2 discloses a free-free beam MEMS vibrator having a structure of improving vibration characteristics by properly setting the length of the support portion with respect to the frequency of vibration.

However, in the MEMS vibrator disclosed in U.S. Pat. No. 6,930,569 B2, since a beam (support portion) that supports a vibrating portion is linearly extended in a direction intersecting the vibrating portion to be fixed to the substrate or the like, stress is concentrated on the support portion or the like when strain is generated between the substrate and the vibrating portion, leading to a risk of breakage of the MEMS vibrator.

### SUMMARY

An advantage of some aspects of the invention is to solve at least a part of the problems described above, and the invention can be realized as the following application examples or modes.

### Application Example 1

A vibrator according to this application example includes: a vibrating portion; a support portion extended from the vibrating portion; and a fixing portion disposed at the support portion, wherein the support portion includes a first beam portion extending in a first direction from the vibrating portion and a second beam portion extending in a second direction intersecting the first direction.

According to the vibrator, the support portion includes the first beam portion and the second beam portion. In the vibrator, the first beam portion and the second beam portion are extended respectively in different directions. Therefore, when strain is generated between a base portion and the vibrating portion, deformation due to the strain can be absorbed in at least two different directions.

Therefore, in the vibrator, the beam portions are deformed to thereby absorb the strain generated between the base portion and the vibrating portion, making it possible to suppress the breakage of the vibrator caused by the concentration of stress due to the strain on the support portion.

### Application Example 2

In the vibrator according to the application example described above, it is preferable that the support portion includes a third beam portion extending in a third direction intersecting the second direction.

According to the vibrator, the support portion includes the third beam portion extending in the third direction, in addition to the beam portions extending in the first direction and the second direction. In the vibrator, the third beam portion is disposed to be extended in the direction different from the first beam portion and the second beam portion. Therefore, when strain is generated between the base portion and the vibrating portion, deformation due to the strain can be absorbed in at least three different directions.

Therefore, in the vibrator, the support portion is deformed to thereby absorb the strain generated between the base portion and the vibrating portion, making it possible to suppress the breakage of the vibrator caused by the concentration of stress due to the strain on the support portion.

### Application Example 3

In the vibrator according to the application example described above, it is preferable that the support portion includes a fourth beam portion extending in a fourth direction intersecting the third direction and a fifth beam portion extending in a fifth direction intersecting the fourth direction.

According to the vibrator, the support portion includes the fourth and fifth beam portions extending in the fourth and fifth directions, respectively, in addition to the beam portions extending in the first to third directions.

In the vibrator, the fourth beam portion and the fifth beam portion are disposed to be extended in the directions different from the first beam portion to the third beam portion. Therefore, when strain is generated between the base portion and the vibrating portion, deformation due to the strain can be absorbed in at least five different directions.

Therefore, in the vibrator, the support portion is deformed to thereby absorb the strain generated between the base portion and the vibrating portion, making it possible to suppress the breakage of the vibrator caused by the concentration of stress due to the strain on the support portion.

### Application Example 4

A vibrator according to this application example includes: a vibrating portion; a support portion extended from the vibrating portion; and a fixing portion disposed at the support portion, wherein the support portion is disposed to be wound around the fixing portion.

According to the vibrator, the support portion extended from the vibrating portion includes the fixing portion in a direction in which the support portion is extended from the vibrating portion, and is disposed so as to be wound around the fixing portion.

In the vibrator, the support portion is disposed so as to be wound around the fixing portion. Therefore, when strain is generated between the base portion and the vibrating portion, deformation due to the strain can be absorbed in directions about the fixing portion.

### Application Example 5

In the vibrator according to the application example described above, it is preferable that a plurality of the support portions are extended from the vibrating portion.

According to the vibrator, the plurality of support portions extending from the vibrating portion are disposed. In the vibrator, since the plurality of support portions are disposed, the vibrating portion can be stably supported.

### Application Example 6

In the vibrator according to the application example described above, it is preferable that the support portion is disposed, in a direction intersecting a direction in which the support portion is extended, at positions that are point symmetrical about a point on an imaginary line passing through the center of the vibrator.

According to the vibrator, the support portion is extended from the positions of the vibrating portion, where the positions are point symmetrical about the point on the imaginary line in the direction intersecting the direction in which the support portion is extended. In the vibrator, since the support portion is disposed in both directions of the vibrating portion, the vibrating portion can be stably supported.

### Application Example 7

A manufacturing method of a vibrator according to this application example includes: forming the vibrating portion and the support portion; and forming the fixing portion and a lower electrode, wherein the forming of the vibrating portion and the support portion includes forming at least two beam portions that are extended in different directions.

According to the manufacturing method, in the forming of the vibrating portion and the support portion, forming of the at least two beam portions that are extended in different directions is included. With this configuration, in the forming of the vibrating portion and the support portion, the beam portions that are extended in different directions can be formed in the support portion that is extended from the vibrating portion toward the fixing portion. Accordingly, when strain is generated between the vibrating portion and the base portion disposed with the fixing portion, the plurality of beam portions are deformed to thereby absorb the strain generated between the base portion and the vibrating portion, making it possible to suppress the breakage of the vibrator caused by the concentration of stress due to the strain on the support portion.

### Application Example 8

An electronic apparatus according to this application example includes the vibrator according to the application example.

According to the electronic apparatus, since the vibrator whose breakage due to stress is suppressed is mounted, the electronic apparatus with high reliability can be obtained.

### Application Example 9

A moving object according to this application example includes the vibrator according to the application example described above.

According to the moving object, since the vibrator whose breakage due to stress is suppressed is mounted, the moving object with high reliability can be obtained.

### BRIEF DESCRIPTION OF THE DRAWINGS

The invention will be described with reference to the accompanying drawings, wherein like numbers reference like elements.

FIG. 1 is a perspective view showing a schematic configuration of a vibrator according to an embodiment.

FIG. 2 is a plan view showing a schematic configuration of the vibrator according to the embodiment.

FIG. 3 is a cross-sectional view showing a schematic configuration of the vibrator according to the embodiment.

FIG. 4 is a cross-sectional view showing a schematic configuration and an operating state of the vibrator according to the embodiment.

FIG. 5 is an enlarged view schematically showing, in an enlarged manner, a portion of a support portion of the vibrator according to the embodiment.

FIGS. 6A1 to 6B2 are cross-sectional views showing manufacturing steps of the vibrator according to the embodiment.

FIGS. 7C1 to 7D2 are cross-sectional views showing manufacturing steps of the vibrator according to the embodiment.

FIGS. 8E1 to 8F2 are cross-sectional views showing manufacturing steps of the vibrator according to the embodiment.

FIGS. 9G1 and 9G2 are cross-sectional views showing manufacturing steps of the vibrator according to the embodiment.

FIG. 10A is an enlarged view schematically showing, in an enlarged manner, a portion of a support portion according to Modified Example 1; and FIG. 10B is an enlarged view schematically showing, in an enlarged manner, a portion of a support portion according to Modified Example 2.

FIG. 11A is an enlarged view schematically showing, in an enlarged manner, a portion of a support portion according to Modified Example 3; and FIG. 11B is an enlarged view schematically showing, in an enlarged manner, a portion of a support portion according to Modified Example 4.

FIG. 12 is a perspective view showing an electronic apparatus according to an embodiment.

FIG. 13 is a perspective view showing an electronic apparatus according to an embodiment.

FIG. 14 is a perspective view showing an electronic apparatus according to an embodiment.

FIG. 15 is a perspective view showing a moving object according to an embodiment.

### DESCRIPTION OF EXEMPLARY EMBODIMENTS

Hereinafter, an embodiment of the invention will be described with reference to the drawings. In the drawings described below, the dimensions and ratios of components are sometimes shown different from actual ones as appropriate to show the components in sizes recognizable on the drawings.

### Embodiment

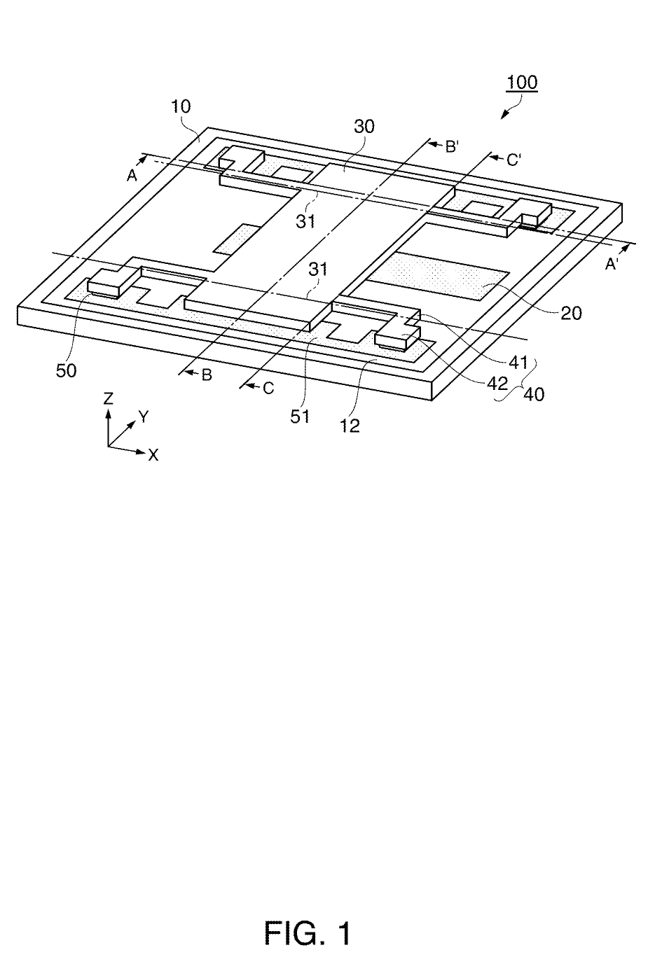

A vibrator according to the embodiment will be described with reference to FIGS. 1 to 9G2.

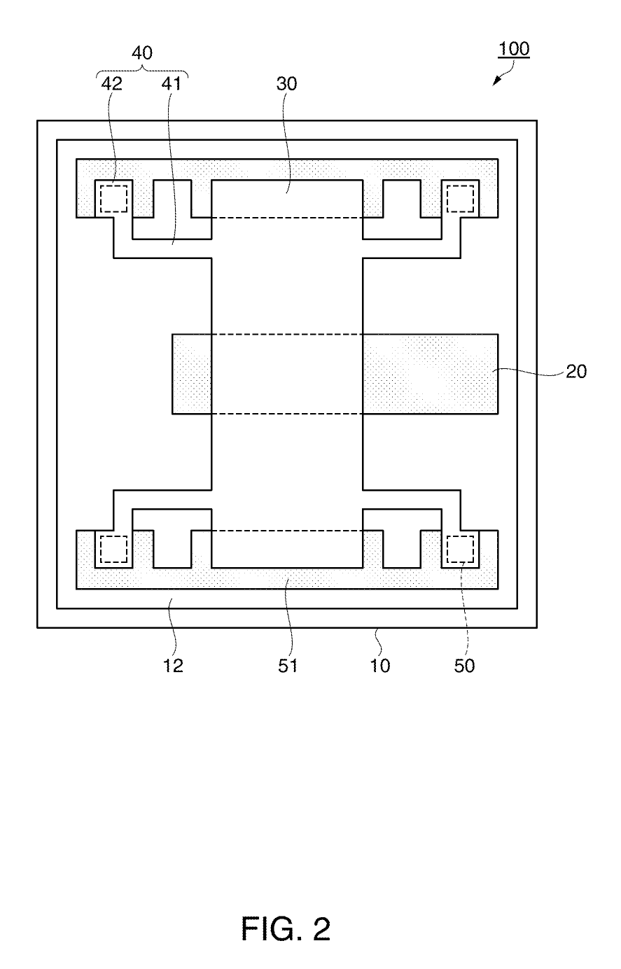

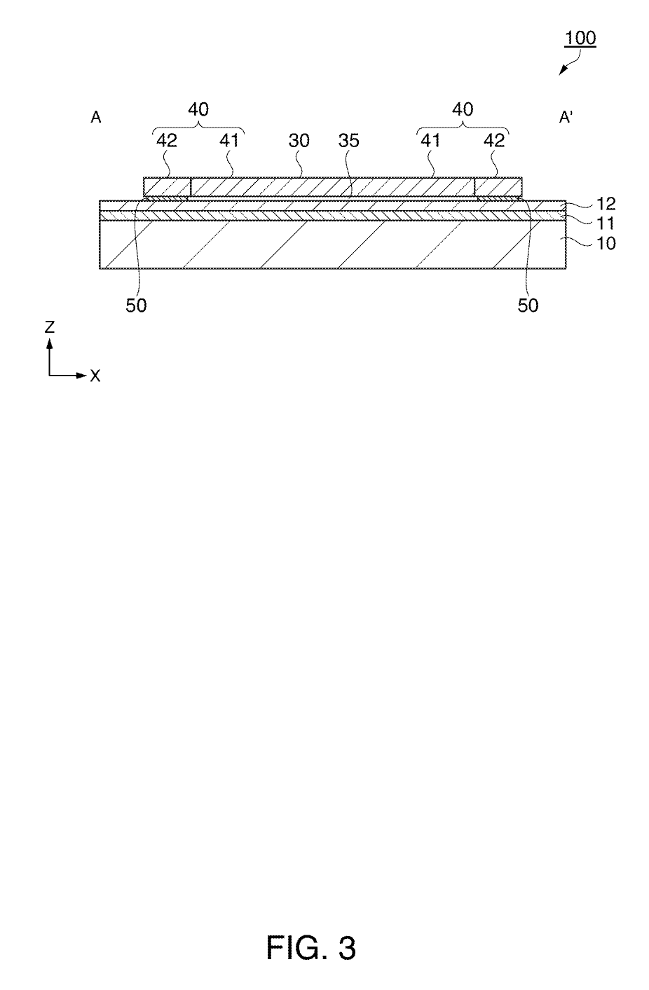

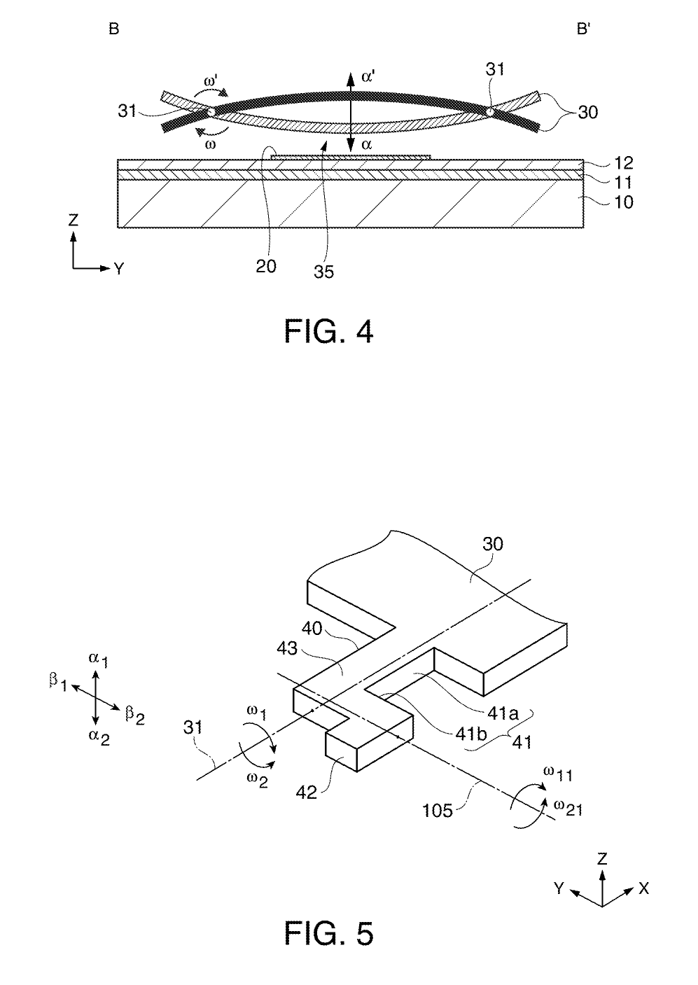

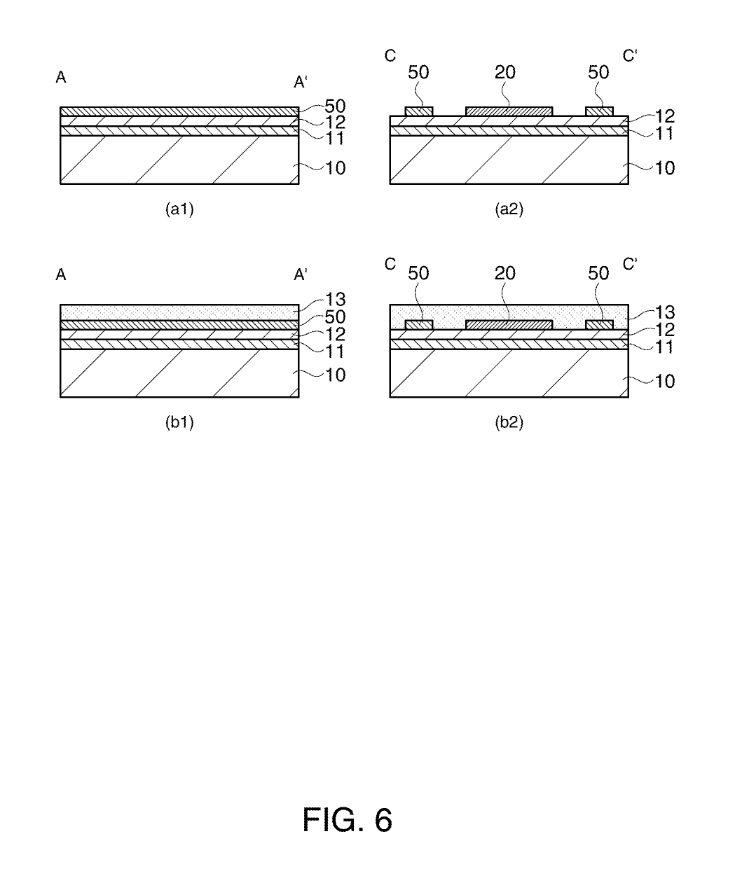

FIG. 1 is a perspective view schematically showing a MEMS vibrator as the vibrator according to the embodiment. FIG. 2 is a plan view schematically showing the MEMS vibrator. FIGS. 3 and 4 are cross-sectional views schematically showing cross-sections of the MEMS vibrator shown in FIG. 1. FIG. 5 is an enlarged view schematically showing, in an enlarged manner, a portion of a support portion of the MEMS vibrator shown in FIG. 1. FIGS. 6A1 to FIG. 9G2 are step diagrams for explaining a manufacturing method of the MEMS vibrator as the vibrator according to the embodiment.

The MEMS vibrator 100 as the vibrator according to the embodiment includes, above a substrate 10, a vibrating portion 30, support portions 40 extended from the vibrating portion 30, and fixing portions 50 fixing the support portions 40. Moreover, the MEMS vibrator 100 includes, on the substrate 10 as a base portion fixing the vibrating portion 30, a lower electrode 20 for vibrating the vibrating portion 30. The support portion 40 is configured to include a beam portion 41 and a post portion 42.

In the MEMS vibrator 100, the vibrating portion 30 is fixed via the fixing portions 50 to the substrate 10 by means of the support portions 40 extended from the vibrating portion 30. In the support portion 40, the beam portion 41 is extended from the vibrating portion 30, the post portion 42 is disposed at one end of the beam portion 41 on the side opposite to the vibrating portion 30, and the post portion 42 and the fixing portion 50 are connected to each other.

The vibrating portion 30 is disposed with a gap 35 so as to overlap, when viewed planarly from a Z-axis direction in FIG. 1, the lower electrode 20 disposed on the substrate 10. The vibrating portion 30 is disposed so as to overlap the lower electrode 20 with the gap 35, thereby being capable of vibrating. Operations of the vibrating portion 30 will be described later.

The substrate 10 is a base portion (base material) mounted with the vibrating portion 30 and the like. For the substrate 10, it is preferred to use a silicon substrate that is easily processed by a semiconductor processing technique. The substrate 10 is not limited to a silicon substrate, and for example, a glass substrate can be used.

As shown in FIG. 3, an insulating film 11 and an under film 12 stacked on the insulating film 11 are disposed on the substrate 10. On the under film 12, the lower electrode 20 and the fixing portions 50 are disposed.

The insulating film 11 is disposed on substantially the entire surface of the substrate 10 as viewed from the Z-axis direction shown in FIG. 1 to FIG. 3. As the insulating film 11, a LOCOS (local oxidation of silicon) film, for example, is used.

The under film 12 is disposed corresponding to (to be stacked on) the insulating film 11 described above. As the under film 12, a silicon nitride (SiN) film, for example, is used.

The lower electrode 20 is disposed on the under film 12 described above. The lower electrode 20 is an electrode patterned into, for example, a rectangular shape. As the material of the lower electrode 20, a conductive member such as gold (Au) or aluminum (Al) is used.

The fixing portion 50 is disposed on the under film 12 similarly to the lower electrode 20 described above. More specifically, the fixing portion 50 is disposed to be stacked on a conductive film 51 disposed on the under film 12. The fixing portion 50 is an electrode patterned into, for example, a rectangular shape. As the material of the fixing portion 50 and the conductive film 51, a conductive member such as gold (Au) or aluminum (Al) is used.

The vibrating portion 30 and the support portions 40 are disposed above the substrate 10 as viewed from the Z-axis direction shown in FIGS. 1 to 3.

The vibrating portion 30 is disposed to face the lower electrode 20 described above with the gap 35.

The support portion 40 is extended from the vibrating portion 30 toward the fixing portion 50 described above.

In the support portion 40, the beam portion 41 is extended from the vibrating portion 30 toward the fixing portion 50, and the post portion 42 is disposed at the end of the beam portion 41 and connected to the fixing portion 50.

More specifically, the beam portion 41 includes a beam portion 41a as a first beam portion extending in a first direction and a beam portion 41b as a second beam portion extending in a second direction intersecting the first direction.

In the beam portion 41, the beam portion 41a is extended as a portion of the support portion 40 from the vibrating portion 30, the beam portion 41b is connected to the other end of the beam portion 41a extending from the vibrating portion 30 and is extended from the beam portion 41a, and the post portion 42 is connected to the other end of the beam portion 41b extending from the beam portion 41a.

With this configuration, the vibrating portion 30 is connected to the fixing portions 50 by means of the support portions 40, thereby being fixed to the substrate 10. In the MEMS vibrator 100, since the gap 35 is disposed between the vibrating portion 30 and the lower electrode 20, the vibrating portion 30 can vibrate.

The vibrating portion 30 is patterned into, for example, a rectangular shape, has conductivity, and functions as a movable electrode described later. As the material of the vibrating portion 30, polysilicon (polycrystalline silicon) is used.

FIG. 4 is a cross-sectional view of the MEMS vibrator 100 taken along line B-B′ shown in FIG. 1, showing the vibration operation of the vibrating portion 30.

Due to an electrostatic force of charge generated by an AC voltage applied between the lower electrode 20 and the vibrating portion 30 as a movable electrode, the vibrating portion 30 is attracted to and separated from the lower electrode 20 in a repetitive manner to thereby perform a bending vibration motion. A signal caused by the vibration is output between the electrodes.

The vibration of the vibrating portion 30 (movable electrode) is a flexural vibration operation in which a central portion, at which the lower electrode 20 and the vibrating portion 30 overlap each other, and both ends of the vibrating portion 30 serve as antinodes of vibration and nodes 31 of vibration are provided between the antinodes of vibration. In other words, the vibration of the vibrating portion 30 is a bending motion operation with the nodes 31 each being as a supporting point.

At the node 31 of vibration, forces W and W′ in the rotational axis direction of the node 31 are generated. Moreover, in the vibrating portion 30, forces a and a′ in the Z-axis direction are generated with the vibration motion.

The support portions 40 are connected to the vibrating portion 30 at the portions of the nodes 31 of vibration. In other words, the beam portions 41 are extended from the node 31 of vibration of the vibrating portion 30.

Specifically, the vibrating portion 30 is supported by the support portions 40 at both ends of each of the nodes 31 of vibration shown by a chain line and denoted by the reference numeral 31 in FIG. 1.

A plurality of support portions 40 are extended from the vibrating portion 30 in the MEMS vibrator 100 of the embodiment shown in FIG. 1. It is preferred that the support portions 40 are extended in opposite directions from the vibrating portion 30 at each of the nodes 31 of vibration and that the vibrating portion 30 is supported by two pairs (two sets) of support portions 40.

The support of the vibrating portion 30 is not limited thereto, and the support portion 40 may be disposed in one direction from the node 31 of vibration. Moreover, the support portions 40 may be disposed from the vibrating portion 30 alternately in opposite directions at each of the nodes 31 of vibration.

Moreover, the support portion 40 may be extended from the positions of the vibrating portion 30, where the positions are point symmetrical about a point (not shown) on an imaginary line (for example, the line B-B′ shown in FIG. 1) passing through the center of the vibrating portion 30 in a direction in which the vibrating portion 30 extends.

Moreover, the support portion 40 may be disposed at any of the nodes 31 of vibration. That is, one support portion 40 may support the vibrating portion 30.

Although, in FIGS. 1 to 4, wiring for extracting a signal caused by vibration is disposed on the lower electrode and the vibrating portion 30 (movable electrode), description and illustration in each drawing are omitted.

Here, the support portion 40 will be described in detail with reference to FIG. 5.

FIG. 5 is a perspective view schematically showing, in an enlarged manner, the portion of the beam portion 41 constituting the support portion 40. In the support portion 40 shown in FIG. 5, the beam portion 41 is shown as viewed perspectively from a direction in which the beam portion 41 is extended from the vibrating portion 30.

The support portion 40 includes the beam portion 41a and the beam portion 41b between the vibrating portion 30 and the fixing portion 50, where the support portion 40 is extended therebetween. In the support portion 40, the beam portion 41a is extended in the first direction (X-axis direction) from the vibrating portion 30, the beam portion 41b is extended in the second direction (Y-axis direction) intersecting the direction in which the beam portion 41a is extended, and the beam portion 41b is connected to the post portion 42. In other words, the beam portion 41 has an L-shape.

In the following description, a portion at which the beam portion 41a and the beam portion 41b are connected to each other is referred to as a connecting point 43.

In the support portion 40 of the MEMS vibrator 100 of the embodiment, the beam portion 41 has an “L-shape”. Therefore, when strain is generated between the substrate 10 (illustration is omitted in FIG. 5) and the vibrating portion 30, the beam portion 41 can be deformed (displaced) with the connecting point 43 being as a supporting point.

For example, when strain is generated in a direction in which a gap between the vibrating portion 30 and the substrate 10 disposed with the fixing portions 50 (illustration is omitted in FIG. 5) is widened or narrowed, that is, in the Z-axis direction, the beam portion 41a and the beam portion 41b can be displaced with the connecting point 43 being as a supporting point in shear directions α₁ and α₂ of the beam portion 41 shown in FIG. 5.

More specifically, when strain is generated in a direction in which the gap between the vibrating portion 30 and the substrate 10 is widened, the beam portion 41a can be displaced in the direction α₁ with the connecting point 43 being as a supporting point. The beam portion 41b can be twisted and displaced in a rotational axis direction ω₂₁ of a center line 105 that is the center of the beam portion 41b in the extension direction (Y-axis direction) thereof.

For example, when strain is generated in a direction in which the gap between the vibrating portion 30 and the substrate 10 is narrowed, the beam portion 41a can be displaced in the direction α₂ with the connecting point 43 being as a supporting point, while the beam portion 41b can be twisted and displaced in a rotational axis direction ω₁₁ of the center line 105.

On the other hand, when strain is generated in the horizontal directions (X-axis direction and Y-axis direction) in the vibrating portion 30 and the substrate 10, the beam portion 41a can be displaced in shear directions α₁, β₂, β₁, and β₂ according to the strain with the connecting point 43 being as a supporting point. Moreover, the beam portion 41a extending from the node 31 of vibration can be displaced in rotational axis directions ω₁ and ω₂ of the node 31. The beam portion 41b can be displaced in the shear directions α₁, α₂, β₁, and β₂ with the connecting point 43 being as a supporting point. Moreover, the beam portion 41b can be displaced in the rotational axis directions ω₁₁ and ω₂₁ of the center line 105.

With this configuration, even when strain is generated between the vibrating portion 30 and the substrate 10, the beam portion 41 is deformed to absorb the strain, making it possible to suppress the breakage of the vibrating portion 30 and the support portion 40.

### Manufacturing Method

Next, a manufacturing method of the MEMS vibrator 100 will be described.

FIGS. 6A1 to 9G2 are step diagrams showing the manufacturing method of the MEMS vibrator in the order of steps.

The manufacturing method of the MEMS vibrator 100 can include a step of forming the vibrating portion 30 and the support portion 40, a step of forming the fixing portion 50 and the lower electrode 20, and a step of removing an intermediate layer after forming the support portion 40.

In FIGS. 6A1 to 9G2, A1 to G1 show a cross-section taken along line A-A′ shown in FIG. 1, while A2 to G2 show a cross-section taken along line C-C′ shown in FIG. 1. Moreover, in FIGS. 6A1 to 9G2, when FIG. 6A is referred to for example, it includes FIGS. 6A1 and 6A2 in the following description. Moreover, in FIGS. 6A1 to 9G2, the fixing portion 50 and the conductive film 51 are shown in a simplified manner and collectively shown as the fixing portion 50.

FIG. 6A shows a state where the lower electrode 20 and the fixing portion 50 (the conductive film 51) are disposed above the substrate 10.

The formation of the lower electrode 20 and the fixing portion 50 is as follows. The substrate 10 is prepared, and the insulating film 11 is disposed on a surface serving as a principal surface. As a forming method of the insulating film 11, a general LOCOS (local oxidation of silicon) film can be formed using a CVD (chemical vapor deposition) method, for example.

Next, the under film 12 is stacked corresponding to the insulating film 11. As a forming method of the under film 12, a silicon nitride (SiN) film can be formed using a CVD method, for example. The under film 12 using a silicon nitride film is resistant to a cleaning liquid (etchant) containing hydrofluoric acid and can function as a so-called etching stopper.

Next, the lower electrode 20 and the fixing portion 50 are formed on the under film 12. As a forming method of the lower electrode 20 and the fixing portion 50, a conductive film can be disposed using a photolithography method, for example. The forming material of a conductive film is not particularly limited, but a conductive material containing aluminum (AL), copper (Cu), gold (Au), or the like can be used.

FIG. 6B shows a state where a sacrificial layer 13 is disposed as an intermediate layer for disposing the gap 35 (refer to FIGS. 3 and 4) between the lower electrode 20 and the vibrating portion 30.

The sacrificial layer 13 is formed by being stacked on the under film 12, the lower electrode 20, and the fixing portions 50. The sacrificial layer 13 is temporarily disposed for disposing the gap 35 between the vibrating portion 30 and a portion of the support portion 40, and the under film 12, the lower electrode 20, and the fixing portion 50, which will be described later. As a forming method of the sacrificial layer 13, a silicon oxide (SiO₂) film can be disposed using a CVD method, for example.

On the sacrificial layer 13, a silicon layer (film) 14 serving as the vibrating portion 30 and the support portion 40 is formed by being stacked on the sacrificial layer 13 in a later step. Therefore, it is preferable to planarize a surface of the sacrificial layer 13. The planarization of the sacrificial layer 13 can be performed by, for example, a CMP (chemical mechanical polishing) method.

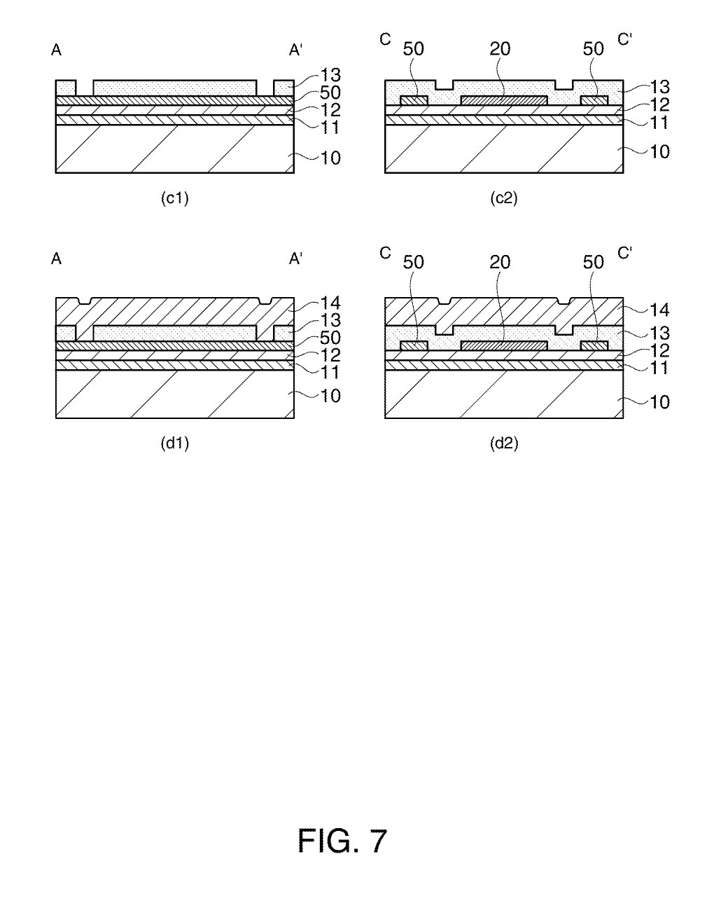

FIG. 7C shows a state where the sacrificial layer 13 is removed (etched) at portions at each of which the support portion 40 is connected to the fixing portion 50. Specifically, FIG. 7C1 shows a state where the sacrificial layer 13 at portions each serving as the fixing portion 50 that connects the post portion 42 of the support portion 40 is removed to expose the fixing portion 50. FIG. 7C2 shows a state where the sacrificial layer 13 at portions each serving as the beam portion 41 is removed. The partial removal of the sacrificial layer 13 can be performed by a photolithography method.

FIG. 7D shows a state where the silicon layer 14 serving as the vibrating portion 30 and the support portion 40 is formed. The silicon layer 14 is formed corresponding to the sacrificial layer 13 or to the sacrificial layer 13 and the fixing portion 50. As a forming method of the silicon layer 14, a polysilicon layer can be disposed using a CVD method, for example.

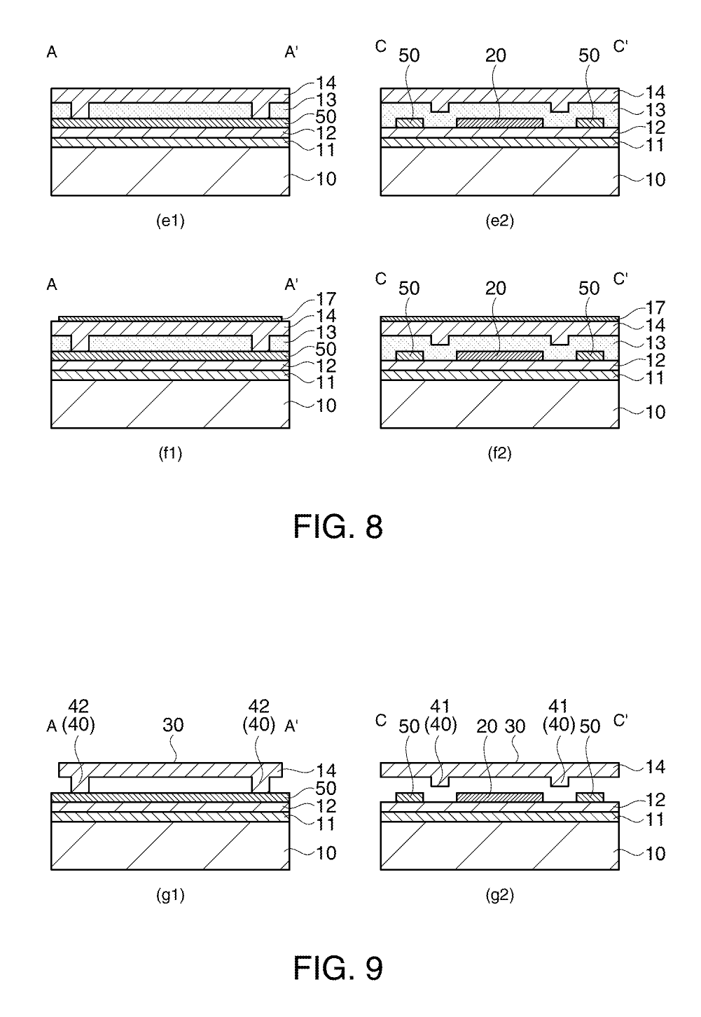

FIG. 8E shows a state where the silicon layer 14 is planarized. Since the silicon layer 14 is formed to include the portions at which the sacrificial layer 13 is removed as described above, a depression (recess) is generated at the portions at which the sacrificial layer 13 is removed. When the depression is generated, there is a risk that the thicknesses of the vibrating portion 30 and the support portion 40 formed of the silicon layer 14 become uneven. Because of this, it is preferable to planarize the silicon layer 14. The planarization of the silicon layer 14 can be performed by a CMP method similarly to the planarization of the sacrificial layer 13 described above. Even when the silicon layer 14 is not planarized, functions as the MEMS vibrator 100 are provided. However, planarizing is preferred for stabilizing the vibration operation.

FIG. 8F shows a state where the silicon layer 14 is patterned with a resist film 17 for forming the shapes of the vibrating portion 30 and the support portion 40.

On the silicon layer 14, the resist film. 17 is formed at portions that are necessary as the vibrating portion 30 and the support portion 40. With this configuration, the silicon layer 14 at portions not formed with the resist film 17 is removed, so that the vibrating portion 30 and the support portion 40 can be formed.

The removal of the silicon layer 14 can be performed by, for example, a photolithography method.

FIG. 9G shows a state where the sacrificial layer 13 is removed and the shapes of the vibrating portion 30 and the support portion 40 appear.

The removal of the sacrificial layer 13 can be performed by, for example, a wet etching method using a cleaning liquid (etchant) that can selectively etch the sacrificial layer 13. As a cleaning liquid, a cleaning liquid containing hydrofluoric acid can be used. With the use of such a cleaning liquid, the sacrificial layer 13 formed of a silicon oxide film can be selectively removed (etched), while the insulating film 11 formed of a LOCOS film can be protected by the under film 12 formed of a silicon nitride film.

With the completion of the removal of the sacrificial layer 13, the manufacturing steps of the MEMS vibrator 100 are completed.

According to the embodiment described above, the following advantageous effects are obtained.

According to the MEMS vibrator 100, since the step of forming a plurality of beam portions 41 that are extended in different directions is included in forming the vibrating portion 30 and the support portion 40, the plurality of beam portions 41 that are extended in different directions can be disposed in the support portion 40. Moreover, the plurality of beam portions 41 are disposed in the support portion 40 extending from the vibrating portion 30 to the fixing portion 50 that is disposed on the substrate 10. Therefore, when strain is generated between the vibrating portion 30 and the substrate 10, the beam portion 41 can be deformed to thereby absorb the strain in a plurality of directions according to the direction in which the beam portion 41 is extended. Therefore, the breakage of the MEMS vibrator 100 can be suppressed.

The invention is not limited to the embodiment described above, and modifications or improvements can be added to the embodiment described above. Modified examples will be described below. The same components as those of the embodiment described above are denoted by the same reference numerals and signs, and redundant description is omitted.

### Modified Example 1

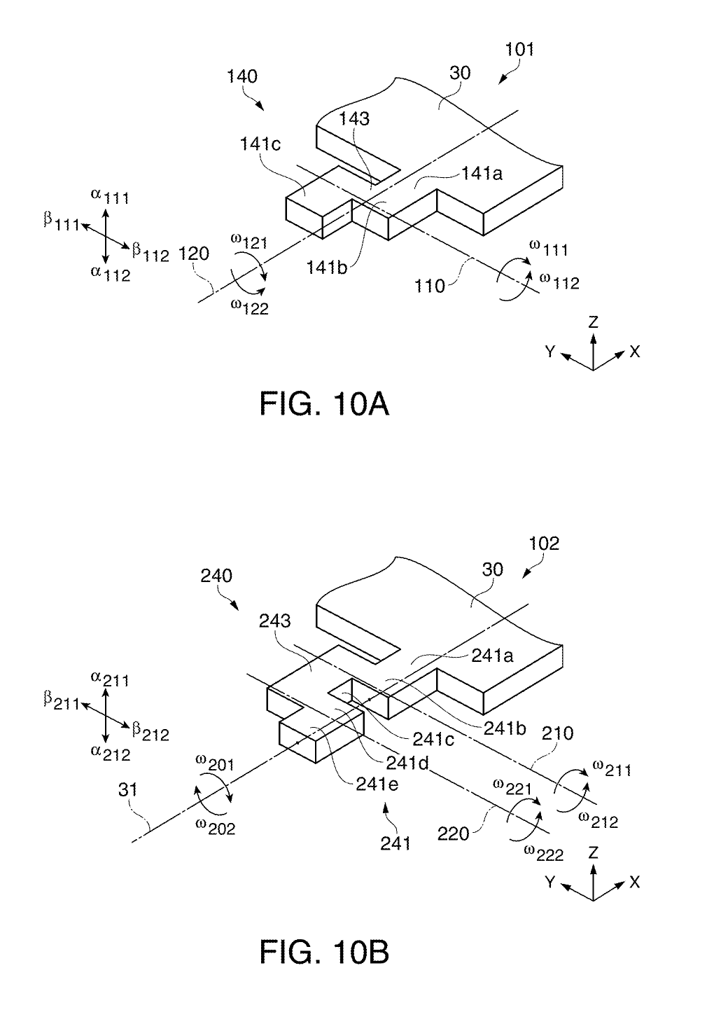

FIG. 10A is an enlarged perspective view of a support portion 140 of a MEMS vibrator 101 according to Modified Example 1.

The MEMS vibrator 101 is a MEMS vibrator including a free-free beam movable electrode similarly to the MEMS vibrator 100. The MEMS vibrator 101 is configured to include the substrate 10, the lower electrode 20, the vibrating portion 30, the fixing portion 50, and the support portion 140. In FIG. 10A, the illustration of these components is partially omitted.

The support portion 140 differs from the support portion 40 of the MEMS vibrator 100 described above in the shape of a beam portion 141. The beam portion 141 includes a beam portion 141a, a beam portion 141b, and a beam portion 141c between the vibrating portion 30 and the fixing portion 50, where the beam portion 141 is extended therebetween.

In the support portion 140, the beam portion 141a as a first beam portion is extended in the first direction (X-axis direction) from the vibrating portion 30, the beam portion 141b as a second beam portion is extended in the second direction (Y-axis direction) intersecting the direction in which the beam portion 141a is extended, the beam portion 141c as a third beam portion is extended in a third direction (X-axis direction) intersecting the direction in which the beam portion 141b is extended, and the beam portion 141c is connected to a post portion (not shown in FIG. 10A). In other words, the beam portion 141 has a crank shape.

In the following description, the center of the beam portion 141b extended in the second direction in each of the extension direction (Y-axis direction) and in the width direction (X-axis direction) of the beam portion 141b, which is a direction intersecting the extension direction, is referred to as a center point 143.

Since the support portion 140 of the MEMS vibrator 101 according to Modified Example 1 includes a plurality of bends (crank shape) in the beam portion 141, the beam portion 141 can be deformed (displaced) with the center point 143 being as a supporting point when strain is generated between the substrate 10 (illustration is omitted in FIG. 10A) and the vibrating portion 30.

For example, when strain is generated in the direction in which the gap between the vibrating portion 30 and the substrate 10 is widened or narrowed, that is, in the Z-axis direction, the beam portion 141a and the beam portion 141c can be displaced with the center point 143 being as a supporting point in shear directions α₁₁₁ and α₁₁₂ of the beam portion 141 shown in FIG. 10A. The beam portion 141b can be twisted and displaced in rotational axis directions ω₁₁₁ and ω₁₁₂ of a center line 110 that is the center of the beam portion 141b in the extension direction (Y-axis direction) thereof.

More specifically, when strain is generated in, for example, the direction in which the gap between the vibrating portion 30 and the substrate 10 is widened, the beam portion 141c is displaced in the direction α₁₁₁ with the center point 143 being as a supporting point, while the beam portion 141a is displaced in the direction α₁₁₂ with the center point 143 being as a supporting point. Moreover, the beam portion 141b can be twisted and displaced in the rotational axis direction ω₁₁₁ of the center line 110.

For example, when strain is generated in the direction in which the gap between the vibrating portion 30 and the substrate 10 is narrowed, the beam portion 141c can be displaced in the direction α₁₁₂ with the center point 143 being as a supporting point, while the beam portion 141a can be displaced in the direction α₁₁₁ with the center point 143 being as a supporting point. Moreover, the beam portion 141b can be twisted and displaced in the rotational axis direction ω₁₁₂ of the center line 110.

On the other hand, when strain is generated in the horizontal directions (X-axis direction and Y-axis direction) in the vibrating portion 30 and the substrate 10, the beam portion 141a and the beam portion 141c can be displaced in shear directions α₁₁₁, α₁₁₂, β₁₁₁, and β₁₁₂ according to the strain with the center point 143 being as a supporting point. Moreover, the beam portion 141b can be twisted and displaced in the rotational axis directions ω₁₁₁ and ω₁₁₂ about the center line 110 according to the strain. Moreover, the beam portion 141a and the beam portion 141c can be twisted and deformed in rotational axis directions ω₁₂₁ and ω₁₂₂ of an imaginary line 120 that extends in both directions orthogonal to the center line 110 at the center point 143.

With this configuration, even when strain is generated between the vibrating portion 30 and the substrate 10, the beam portion 141 is deformed to thereby absorb the strain, making it possible to suppress the breakage of the MEMS vibrator 101 (the vibrating portion 30 and the support portion 140) caused by the concentration of stress due to the strain on the support portion 140.

The other points are similar to those of the MEMS vibrator 100 described above, and therefore, description is omitted.

### Modified Example 2

FIG. 10B is an enlarged perspective view of a support portion 240 of a MEMS vibrator 102 according to Modified Example 2.

The MEMS vibrator 102 is a MEMS vibrator including a free-free beam movable electrode similarly to the MEMS vibrator 100. The MEMS vibrator 102 is configured to include the substrate 10, the lower electrode 20, the vibrating portion 30, the fixing portion 50, and the support portion 240. In FIG. 10B, the illustration of these components is partially omitted.

The support portion 240 differs from the support portion 40 of the MEMS vibrator 100 described above in the shape of a beam portion 241.

The beam portion 241 includes a beam portion 241a, a beam portion 241b, a beam portion 241c, a beam portion 241d, and a beam portion 241e between the vibrating portion 30 and the fixing portion 50, where the beam portion 241 is extended therebetween.

In the support portion 240, the beam portion 241a as a first beam portion is extended in the first direction (X-axis direction) from the vibrating portion 30, and the beam portion 241b as a second beam portion is extended in the second direction (Y-axis direction) intersecting the direction in which the beam portion 241a is extended.

The beam portion 241c as a third beam portion is extended in the third direction (X-axis direction) intersecting the direction in which the beam portion 241b is extended, and the beam portion 241d as a fourth beam portion is extended in a fourth direction (Y-axis direction) intersecting the direction in which the beam portion 241c is extended.

The beam portion 241e as a fifth beam portion is extended in a fifth direction (X-axis direction) intersecting the direction in which the beam portion 241d is extended, and the beam portion 241e is connected to the post portion 42 (not shown in FIG. 10B). In other words, the beam portion 241 has a shape in which the crank shapes of the beam portion 141 described above are connected.

In the following description, the center of the beam portion 241c extended in the third direction in each of the extension direction (X-axis direction) and the width direction (Y-axis direction) of the beam portion 241c, which is a direction orthogonal to the extension direction, is referred to as a center point 243.

Since the support portion 240 of the MEMS vibrator 102 according to Modified Example 2 includes a plurality of bends (crank shape) in the beam portion 241, the beam portion 241 can be deformed (displaced) with the center point 243 being as a supporting point when strain is generated between the substrate 10 (illustration is omitted in FIG. 10B) and the vibrating portion 30.

For example, when strain is generated in the direction in which the gap between the vibrating portion 30 and the substrate 10 is widened or narrowed, that is, in the Z-axis direction, the beam portion 241a, the beam portion 241c, and the beam portion 241e can be displaced with the center point 243 being as a supporting point in shear directions α₂₁₁ and α₂₁₂ of the beam portion 241 shown in FIG. 10B.

The beam portion 241b can be twisted and displaced in rotational axis directions ω₂₁₁ and ω₂₁₂ of a center line 210 that is the center of the beam portion 241b in the extension direction (Y-axis direction) thereof. The beam portion 241d can be twisted and displaced in rotational axis directions ω₂₂₁ and ω₂₂₂ of a center line 220 that is the center of the beam portion 241d in the extension direction (Y-axis direction) thereof.

For example, when strain is generated in the direction in which the gap between the vibrating portion 30 and the substrate 10 is widened, the beam portion 241a, the beam portion 241c, and the beam portion 241e can be displaced in the direction α₂₁₂, the direction α₂₁₁, and the direction α₂₁₁, respectively, with the center point 243 being as a supporting point. The beam portion 241b can be twisted and displaced in the rotational axis direction ω₂₁₂ of the center line 210. The beam portion 241d can be twisted and displaced in the rotational axis direction ω₂₂₂ of the center line 220.

For example, when strain is generated in the direction in which the gap between the vibrating portion 30 and the substrate 10 is narrowed, the beam portion 241a, the beam portion 241c, and the beam portion 241e can be displaced in the direction α₂₁₁, the direction α₂₂₁, and the direction α₂₂₁, respectively, with the center point 243 being as a supporting point. The beam portion 241b can be twisted and displaced in the rotational axis direction ω₂₁₁ of the center line 210. The beam portion 241d can be twisted and displaced in the rotational axis direction ω₂₂₁ of the center line 220.

On the other hand, when strain is generated in the horizontal directions (X-axis direction and Y-axis direction) in the vibrating portion 30 and the substrate 10, the beam portion 241a, the beam portion 241c, and the beam portion 241e can be displaced in shear directions α₂₁₁, α₂₁₂, β₂₁₁, and β₂₁₂ according to the strain with the center point 243 being as a supporting point.

The beam portion 241b can be twisted and displaced in the rotational axis directions ω₂₁₁ and ω₂₁₂ of the center line 210 according to the strain. The beam portion 241d can be twisted and displaced in the rotational axis directions ω₂₂₁ and ω₂₂₂ of the center line 220 according to the strain. Moreover, the beam portion 241a extending from the node 31 of vibration and the beam portion 241e disposed on an imaginary line of the node 31 of vibration can be twisted and deformed in rotational axis directions ω₂₀₁ and ω₂₀₂ of the imaginary line.

With this configuration, even when strain is generated between the vibrating portion 30 and the substrate 10, the beam portion 241 is deformed to thereby absorb the strain, making it possible to suppress the breakage of the MEMS vibrator 102 (the vibrating portion 30 and the support portion 240) caused by the concentration of stress due to the strain on the support portion 240.

The other points are similar to those of the MEMS vibrator 100 described above, and therefore, description is omitted.

### Modified Example 3

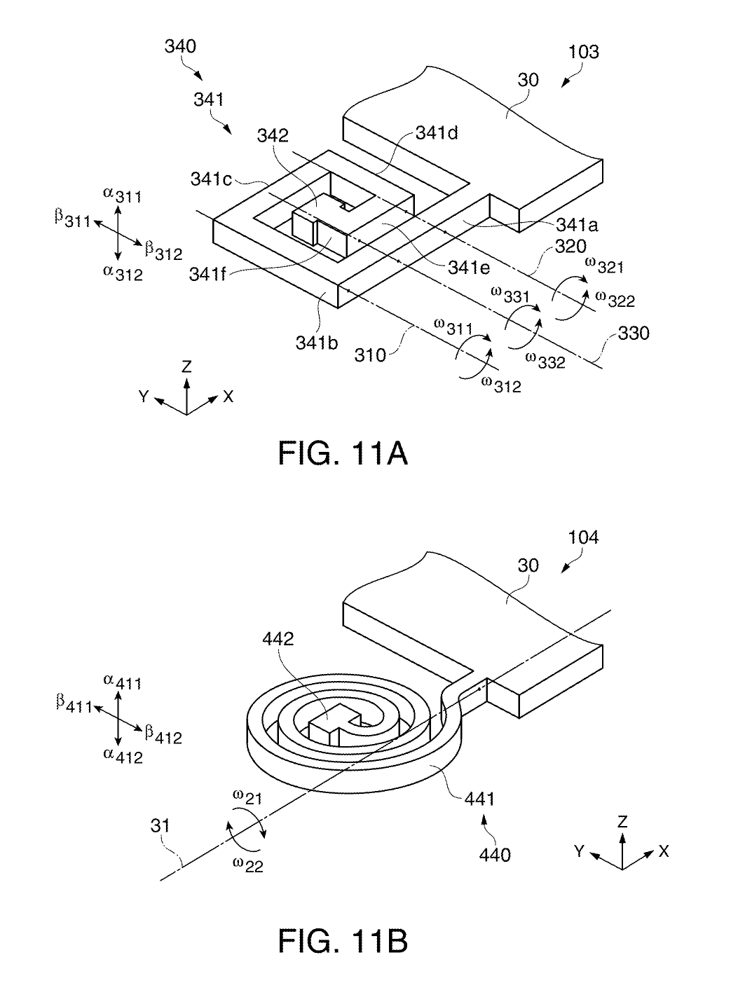

FIG. 11C is an enlarged perspective view of a support portion 340 of a MEMS vibrator 103 according to Modified Example 3.

The MEMS vibrator 103 is a MEMS vibrator including a free-free beam movable electrode similarly to the MEMS vibrator 100. The MEMS vibrator 103 is configured to include the substrate 10, the lower electrode 20, the vibrating portion 30, the fixing portion 50, and the support portion 340. In FIG. 11C, the illustration of these components is partially omitted.

The support portion 340 differs from the support portion 40 of the MEMS vibrator 100 described above in the shape of a beam portion 341.

The beam portion 341 includes a beam portion 341a, a beam portion 341b, a beam portion 341c, a beam portion 341d, a beam portion 341e, and a beam portion 341f between the vibrating portion 30 and the fixing portion 50, where the beam portion 341 is extended therebetween.

In the support portion 340, the beam portion 341a is extended in the first direction (X-axis direction) from the vibrating portion 30, and the beam portion 341b is extended in the second direction (Y-axis direction) intersecting the direction in which the beam portion 341a is extended.

The beam portion 341c is extended in the third direction (X-axis direction) intersecting the direction in which the beam portion 341b is extended, and the beam portion 341d is extended in the fourth direction (Y-axis direction) intersecting the direction in which the beam portion 341c is extended.

The beam portion 341e is extended in the fifth direction (X-axis direction) intersecting the direction in which the beam portion 341d is extended, the beam portion 341f is extended in a sixth direction (Y-axis direction) intersecting the direction in which the beam portion 341e is extended, and the beam portion 341f is connected to a post portion 342. In other words, the beam portion 341 has a shape in which the beam portion 341 is wound by being bent around the fixing portion 50 (the post portion 342).

Since the support portion 340 of the MEMS vibrator 103 according to Modified Example 3 has a shape in which the beam portion 341 is wound by being bent, the beam portion 341 can be deformed (displaced) when strain is generated between the substrate 10 (illustration is omitted in FIG. 11C) and the vibrating portion 30.

For example, when strain is generated in the direction in which the gap between the vibrating portion 30 and the substrate 10 is widened or narrowed, that is, in the Z-axis direction, the beam portion 341a, the beam portion 341c, and the beam portion 341e can be displaced in shear directions α₃₁₁ and α₃₁₂ of the beam portion 341 shown in FIG. 11C.

The beam portion 341b can be twisted and displaced in rotational axis directions α₃₁₁ and α₃₁₂ of a center line 310 that is the center of the beam portion 341b in the extension direction (Y-axis direction) thereof. The beam portion 341d can be twisted and displaced in rotational axis directions ω₃₂₁ and ω₃₂₂ of a center line 320 that is the center of the beam portion 341d in the extension direction (Y-axis direction) thereof. The beam portion 341f can be twisted and displaced in rotational axis directions ω₃₃₁ and ω₃₃₂ of a center line 330 that is the center of the beam portion 341f in the extension direction (Y-axis direction) thereof.

On the other hand, when strain is generated in the horizontal directions (X-axis direction and Y-axis direction) in the vibrating portion 30 and the substrate 10, the beam portions 341a to 341f can be displaced in the shear directions α₃₁₁ and α₃₁₂ according to the strain with the post portion 342 being as a supporting point. Moreover, the beam portions 341a to 341f can be displaced in directions circling around the post portion from a shear direction β₃₁₁ through a shear direction β₃₁₂ to the shear direction β₃₁₁.

With this configuration, even when strain is generated between the vibrating portion 30 and the substrate 10, the beam portion 341 is deformed to thereby absorb the strain, making it possible to suppress the breakage of the MEMS vibrator 103 (the vibrating portion 30 and the support portion 340) caused by the concentration of stress due to the strain on the support portion 340.

The other points are similar to those of the MEMS vibrator 100 described above, and therefore, description is omitted.

### Modified Example 4

FIG. 11D is an enlarged perspective view of a support portion 440 of a MEMS vibrator 104 according to Modified Example 4.

The MEMS vibrator 104 is a MEMS vibrator including a free-free beam movable electrode similarly to the MEMS vibrator 100. The MEMS vibrator 104 is configured to include the substrate 10, the lower electrode 20, the vibrating portion 30, the fixing portion 50, and the support portion 440. In FIG. 11D, the illustration of these components is partially omitted.

The support portion 440 differs from the support portion 40 of the MEMS vibrator 100 described above in the shape of a beam portion 441. The support portion 440 includes the beam portion 441 and a post portion 442 between the vibrating portion 30 and the fixing portion 50, where the support portion 440 is extended therebetween. In the support portion 440, the beam portion 441 extended from the vibrating portion 30 is disposed so as to be wound around the fixing portion 50. In other words, the beam portion 441 is disposed in a spiral shape around the fixing portion 50 (the post portion 442).

Since the support portion 440 of the MEMS vibrator 104 according to Modified Example 4 has a shape in which the beam portion 441 is wound around the fixing portion 50, the beam portion 441 can be deformed (displaced) when strain is generated between the substrate 10 (illustration is omitted in FIG. 11D) and the vibrating portion 30.

For example, when strain is generated in the direction in which the gap between the vibrating portion 30 and the substrate 10 is widened or narrowed, that is, in the Z-axis direction, the beam portion 441 can be displaced in directions circling around the post portion from a shear direction α₄₁₁ through a shear direction α₄₁₂ to the shear direction α₄₁₁ of the beam portion 441 shown in FIG. 11D.

On the other hand, when strain is generated in the horizontal directions (X-axis direction and Y-axis direction) in the vibrating portion 30 and the substrate 10, the beam portion 441 can be displaced with the post portion 442 being as a supporting point in directions circling around the post portion from a shear direction β₄₁₁ through a shear direction β₄₁₂ to the shear direction β₄₁₁ according to the strain.

With this configuration, even when strain is generated between the vibrating portion 30 and the substrate 10, the beam portion 441 is deformed to thereby absorb the strain, making it possible to suppress the breakage of the MEMS vibrator 104 (the vibrating portion 30 and the support portion 440) caused by the concentration of stress due to the strain on the support portion 440.

The other points are similar to those of the MEMS vibrator 100 described above, and therefore, description is omitted.

In the beam portions 41 extending in the first to fifth directions shown in the embodiment and modified examples described above, the extension direction of the beam portion 41 is not limited. For example, the beam portion 41 may be extended in the second direction intersecting the first direction at an angle of 30°. That is, it is sufficient that the beam portions 41 next to each other are extended in different directions.

### Electronic Apparatus

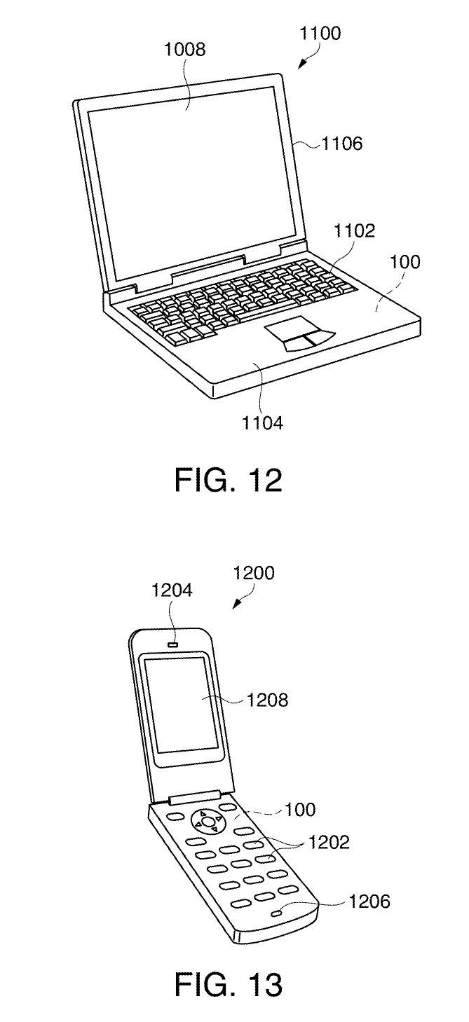

Next, electronic apparatuses to which the MEMS vibrator 100 as an electronic component according to an embodiment of the invention is applied will be described with reference to FIGS. 12 to 15.

FIG. 12 is a perspective view showing a schematic configuration of a mobile (or notebook) personal computer as an electronic apparatus including the MEMS vibrator 100 according to the embodiment of the invention. In the drawing, the personal computer 1100 is composed of a main body portion 1104 including a keyboard 1102 and a display unit 1106 including a display portion 1008. The display unit 1106 is rotatably supported relative to the main body portion 1104 via a hinge structure portion. In the personal computer 1100, the MEMS vibrator 100 as an electronic component that functions as a filter, a resonator, a reference clock, or the like is incorporated.

FIG. 13 is a perspective view showing a schematic configuration of a mobile phone (including a PHS) as an electronic apparatus including the MEMS vibrator 100 according to the embodiment of the invention. In the drawing, the mobile phone 1200 includes a plurality of operation buttons 1202, an earpiece 1204, and a mouthpiece 1206. A display portion 1208 is provided between the operation buttons 1202 and the earpiece 1204. In the mobile phone 1200, the MEMS vibrator 100 as an electronic component (timing device) that functions as a filter, a resonator, an angular velocity sensor, or the like is incorporated.

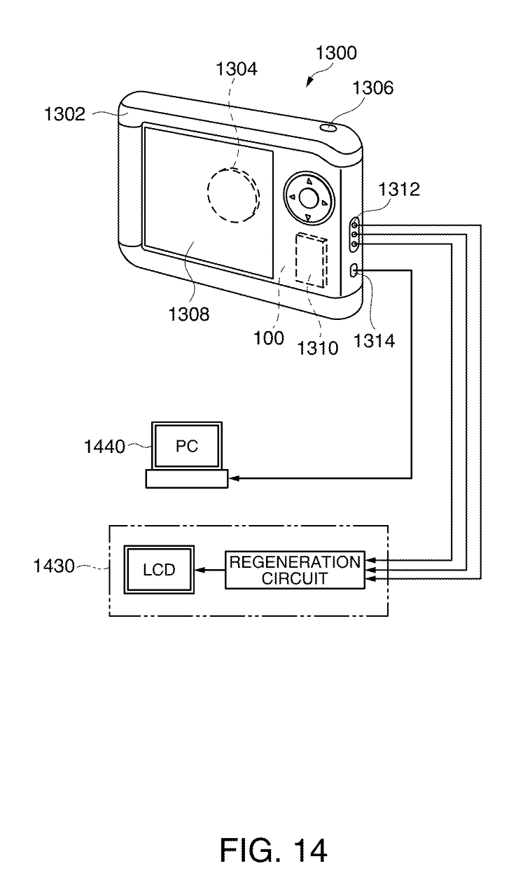

FIG. 14 is a perspective view showing a schematic configuration of a digital still camera as an electronic apparatus including the MEMS vibrator 100 according to the embodiment of the invention. In the drawing, also connections with external apparatuses are shown in a simplified manner. The digital still camera 1300 photoelectrically converts an optical image of a subject with an imaging element such as a CCD (charge coupled device) to generate imaging signals (image signals).

A display portion 1308 is disposed on the back surface of a case (body) 1302 in the digital still camera 1300 and configured to perform display based on imaging signals generated by a CCD. The display portion 1308 functions as a finder that displays a subject as an electronic image. Moreover, on the front side (the rear side in the drawing) of the case 1302, a light receiving unit 1304 including an optical lens (imaging optical system) and a CCD is disposed.

When a photographer confirms a subject image displayed on the display portion 1308 and presses down a shutter button 1306, imaging signals of a CCD at the time are transferred to and stored in a memory 1310. In the digital still camera 1300, a video signal output terminal 1312 and a data communication input/output terminal 1314 are disposed on the side surface of the case 1302. Then, as shown in the drawing, a liquid crystal monitor 1430 and a personal computer 1440 are connected as necessary to the video signal output terminal 1312 and the data communication input/output terminal 1314, respectively. Further, the imaging signals stored in the memory 1310 are output to the liquid crystal monitor 1430 or the personal computer 1440 by a predetermined operation. In the digital still camera 1300, the MEMS vibrator 100 as an electronic component that functions as a filter, a resonator, an angular velocity sensor, or the like is incorporated.

As described above, by applying the MEMS vibrator 100 according to the embodiment of the invention to an electronic apparatus, it is possible to provide an electronic apparatus with higher performance and stable operation.

In addition to the personal computer (mobile personal computer) shown in FIG. 12, the mobile phone shown in FIG. 13, and the digital still camera shown in FIG. 14, the MEMS vibrator 100 as an electronic component according to the embodiment of the invention can be applied to electronic apparatuses such as, for example, inkjet ejection apparatuses (for example, inkjet printers), laptop personal computers, television sets, video camcorders, car navigation systems, pagers, electronic notebooks (including those with communication function), electronic dictionaries, calculators, electronic gaming machines, workstations, videophones, surveillance television monitors, electronic binoculars, POS terminals, medical equipment (for example, electronic thermometers, sphygmomanometers, blood glucose meters, electrocardiogram measuring systems, ultrasonic diagnosis apparatuses, and electronic endoscopes), fishfinders, various types of measuring instrument, indicators (for example, indicators used in vehicles, aircraft, and ships), and flight simulators.

### Moving Object

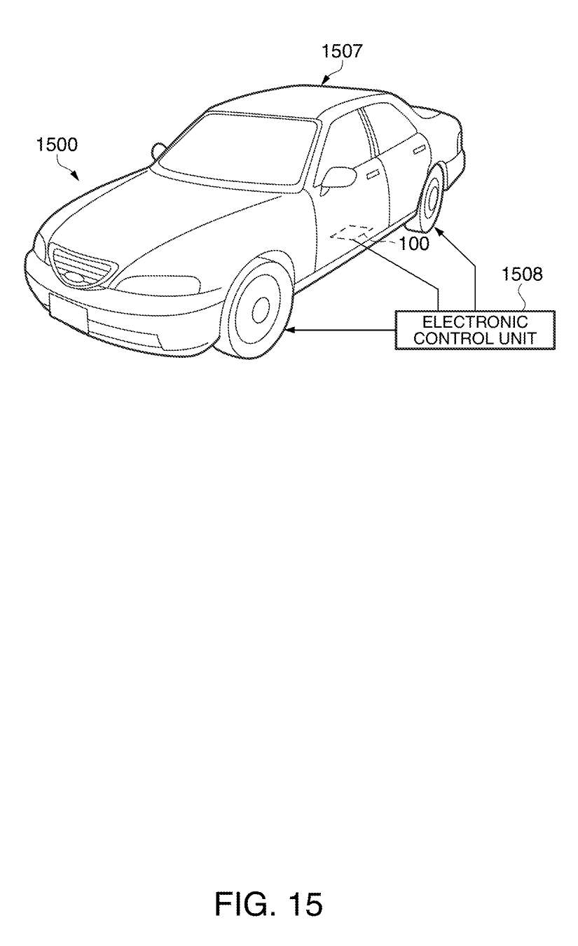

Next, a moving object to which the MEMS vibrator 100 as an electronic component according to the embodiment of the invention is applied will be described with reference to FIG. 15.

FIG. 15 is a perspective view schematically showing an automobile as an example of a moving object. The automobile 1500 includes the MEMS vibrator 100 according to the embodiment of the invention. For example as shown in the drawing, in the automobile 1500 as a moving object, an electronic control unit (ECU) 1508 that incorporates therein, as a sensor that detects acceleration of the automobile 1500, the MEMS vibrator 100 to control an output of an engine is mounted on an automobile body 1507. In addition, the MEMS vibrator 100 can be widely applied to automobile body attitude control units, anti-lock brake systems (ABSs), air bags, and tire pressure monitoring systems (TPMSs).

As described above, by applying the MEMS vibrator 100 according to the embodiment of the invention to a moving object, it is possible to provide a moving object with higher performance and capable of realizing a stable running.

The entire disclosure of Japanese Patent Application No. 2012-260744, filed Nov. 29, 2012 is expressly incorporated by reference herein.

What is claimed is:

1. A vibrator comprising:
a vibrating portion;
a support portion extended from the vibrating portion; and
a fixing portion disposed at the support portion, wherein
the support portion includes a first beam portion extending in a first direction from the vibrating portion and a second beam portion extending in a second direction intersecting the first direction.

2. The vibrator according to claim 1, wherein
the support portion includes a third beam portion extending in a third direction intersecting the second direction.

3. The vibrator according to claim 2, wherein
the support portion includes a fourth beam portion extending in a fourth direction intersecting the third direction and a fifth beam portion extending in a fifth direction intersecting the fourth direction.

4. A vibrator comprising:
a vibrating portion;
a support portion extended from the vibrating portion; and
a fixing portion disposed at the support portion, wherein
the support portion is disposed to be wound around the fixing portion.

5. The vibrator according to claim 1, wherein
a plurality of the support portions are extended from the vibrating portion.

6. The vibrator according to claim 1, wherein
the support portion is disposed, in a direction intersecting a direction in which the support portion is extended, at positions that are point symmetrical about a point on an imaginary line passing through the center of the vibrator.

7. A manufacturing method of a vibrator including a vibrating portion, a support portion extended from the vibrating portion, and a fixing portion disposed at the support portion, wherein the support portion includes a first beam portion extending in a first direction from the vibrating portion and a second beam portion extending in a second direction intersecting the first direction,
the method comprising:
forming the vibrating portion and the support portion; and
forming the fixing portion and a lower electrode, wherein
the forming of the vibrating portion and the support portion includes forming at least two beam portions that are extended in different directions.

8. An electronic apparatus comprising the vibrator according to claim 1.

9. A moving object comprising the vibrator according to claim 1.
